(19) United States
(12) Patent Application Publication
(10) Pub. No.: US 2004/0169564 A1
(43) Pub. Date: Sep. 2, 2004

(54) Voltage-controlled oscillator

(75) Inventor: Yoshinori Muramatsu, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 10/787,129

(22) Filed: Feb. 27, 2004

(30) Foreign Application Priority Data
Feb. 28, 2003 (JP) 2003-054758

(51) Int. Cl. H03B 1/00

(52) U.S. Cl. 331/177 V

(57) ABSTRACT

In a high-stability low-noise voltage-controlled oscillator, a current mirror circuit is connected with a power supply line, and a current controller for controlling a current flowing through the current mirror circuit is disposed between the current mirror circuit and a ground line. In parallel with the current controller, a first negative resistor, an LC circuit, and a second negative resistor are disposed in this order between the current mirror circuit and the ground line. The LC circuit includes an inductor, two variable capacitance elements, and three capacitor pairs. Three control signals are applied such that each control signal is applied to one of N-channel transistors in the current controller and also to one of switch pairs corresponding to one of capacitor pairs in a resonator.

### BACKGROUND OF THE INVENTION

1. Field of the Invention

The present invention relates to a voltage-controlled oscillator using resonance of a parallel LC tank circuit, and more particularly, to a voltage-controlled oscillator including a switched capacitor and capable of generating an oscillating signal which is low in phase noise and whose frequency can be varied stepwisely.

2. Description of the Related Art

It is known in the art to use an LC voltage-controlled oscillator (LC-VCO) using resonance of a parallel LC tank circuit, as a local oscillator (LO) in a phase-locked loop (PLL) for frequency multiplication or phase locking. In the LC-VCO, a parallel LC tank circuit is formed by connecting an inductor and a variable capacitor in parallel, and an AC signal is generated using resonance of the parallel LC tank circuit, wherein the frequency of the generated AC signal is equal to the resonant frequency of the parallel LC tank circuit. The resonant frequency refers to a frequency at which the reactance of the parallel LC tank circuit becomes equal to zero. The resonance refers to a phenomenon in which a current flows alternately through an inductor and a capacitor of the parallel LC tank circuit. A varactor or the like whose capacitance changes in response to an applied control voltage is used as the variable capacitor. When the inductance of the inductor and the capacitance of the capacitor are represented by L and C, the resonant frequency f is given by equation (1) described below.

$$f = \frac{1}{2 π \sqrt{LC}} \qquad ( 1 )$$

From equation (1), it can be seen that the resonant frequency f decreases with increasing capacitance C of the variable capacitor.

Compared with a conventional VCO using a ring oscillator or the like the LC-VCO has following advantages. First, the LC-VCO is low in noise, because the LC-VCO using resonance of the parallel LC tank circuit can be formed of a small number of transistors that are sources of noise. Because of its low noise characteristic, the LC-VCO is suitable for use in high-speed optical communication, portable telephone, wireless LAN, and other similar applications. Second, because the operation of the LC-VCO is based on resonance of the LC circuit, the LC-VCO can easily oscillate at a higher frequency than a VCO which is formed of transistors and which oscillates using delays of logic gates. Third, when a control voltage is varied, the oscillation frequency varies within a small range. This means that the LC-VCO has low tuning sensitivity and has a small fluctuation in oscillation frequency, that is, phase noise, due to a fluctuation in control voltage.

In the parallel LC tank circuit, a change in oscillation frequency results in a change in current flowing through the parallel LC tank circuit. If the angular oscillation frequency is represented by ω₀, the resistance of the parallel LC tank circuit is represented by R_{eff}, and energy consumed by the parallel LC tank circuit is represented by G_{neg}, then equation (2) holds.

G_{neg}=R_{eff}×(ω₀×C)² (2)

As can be seen from equations (1) and (2), if the capacitance C of the variable capacitor is increased to reduce the oscillation frequency f, a current necessary for oscillation increases. If an excessive current is applied to the parallel LC tank circuit, phase noise increases. More specifically, the phase noise L(f_{offset}) at an offset frequency f_{offset} is given by the following equation (3).

$$L ( {f}_{offset} ) = \frac{k \times T \times {R}_{eff} \times ( \frac{1 + {G}_{m , amp}}{{G}_{neg}} ) \times {( \frac{{f}_{osc}}{{f}_{offset}} )}^{2}}{{V}_{rms}^{2}} \qquad ( 3 )$$

In the equation (3), k is the Boltzmann's constant, T is absolute temperature, G_{m,amp} is total energy supplied to the LC-VCO, f_{osc} is the oscillation frequency, and Vᵣₘₛ is the amplitude of the output signal. From equation (3), it can be seen that the phase noise L increases with the ratio (G_{m,amp}/G_{neg}) of energy G_{m,amp} supplied to the LC-VCO to energy G_{neg} consumed by the parallel LC tank circuit.

Therefore, to achieve a stable operation of the LC-VCO, it is necessary to adequately control the current supplied to the parallel LC tank circuit. That is, if the supplied current is too low, the LC-VCO can not oscillate, while if the supplied current is too high, the phase noise becomes high.

In order to control the current supplied to the parallel LC tank circuit of the LC-VCO in synchronization with the operation of the variable capacitor, it is known to control the current in accordance with the control voltage applied to the variable capacitor (a specific example of such a technique may be found, for example, in Japanese Laying Open of Unexamined Application No. 2001-313527). FIG. 1 is a circuit diagram illustrating an equivalent circuit of a conventional LC-VCO disclosed in Japanese Laying Open of Unexamined Application No. 2001-313527. As shown in FIG. 1, the conventional LC-VCO 101 includes a variable current source 102 connected with a power supply line VCC. A control voltage V_{ctrl} is applied to the variable current source 102, and the variable current source 102 outputs a current depending on the control voltage V_{ctrl}.

The current output from the variable current source 102 is input to a current mirror circuit 103. The current mirror circuit 103 is connected with a ground line GND, and the current mirror circuit 103 outputs a current proportional to the current output from the variable current source 102.

The LC-VCO 101 also includes a current mirror circuit 104 connected with the power supply line VCC. The output current of the current mirror circuit 103 is input to the current mirror circuit 104, and the current mirror circuit 104 outputs a current proportional to the output current of the current mirror circuit 103.

Between the current mirror circuit 104 and the ground line GND, there are disposed a negative resistor 105, an LC circuit 106, and a negative resistor 107 in this order from the current mirror circuit 104 to the ground line GND. The LC circuit 106 outputs complementary AC signals generated using LC resonance. The negative resistors 105 and 107 supply currents to the LC circuit 106 in synchronization with the AC signals output from the LC circuit 106.

The variable current source 102 includes two P-channel transistors P101 and P102 connected in parallel with each other. The drain of each of the P-channel transistors P101 and P102 is connected with the power supply line VCC, and the source thereof is connected with a node 111. The gate of the P-channel transistor P101 is connected with a bias voltage terminal T_{B}101 to which a bias voltage is applied, while the gate of the P-channel transistor P102 is connected with a control voltage terminal T_{c}101 to which a control voltage is applied.

The current mirror circuit 103 includes two N-channel transistors N101 and N102. The drain and the gate of the N-channel transistor N101 are connected with the node 111 of the variable current source 102, and the source thereof is connected with the ground line GND. The gate of the N-channel transistor N102 is connected with the node 111, the source is connected with the ground line GND, and the drain is connected with a node 112 of the current mirror circuit 104.

The current mirror circuit 104 includes two P-channel transistors P103 and P104. The source and the gate of the P-channel transistor P103 are connected with the node 112, and the drain is connected with the power supply line VCC. The gate of the P-channel transistor P104 is connected with the node 112, the drain is connected with the power supply line VCC, and the source is connected with a node 113.

The negative resistor 105 includes two P-channel transistors P105 and P106. The drain of the P-channel transistor P105 is connected with the node 113, the source is connected with an output terminal Tₒᵤₜ101 of the LC circuit 106, and the gate is connected with an output terminal Tₒᵤₜ102. The drain of the P-channel transistor 106 is connected with the node 113, the source is connected with the output terminal Tₒᵤₜ102 of the LC circuit 106, and the gate is connected with the output terminal Tₒᵤₜ101.

The LC circuit 106 includes an inductor L101 connected between the output terminals Tₒᵤₜ101 and Tₒᵤₜ102. The LC circuit 106 also includes two variable capacitance diodes D101 and D102. The anode of the variable capacitance diode D101 is connected with the output terminal Tₒᵤₜ101, the anode of the variable capacitance diode D102 is connected with the output terminal Tₒᵤₜ102, and the cathodes of the variable capacitance diodes D101 and D102 are both connected with a node 114 that is connected with the control voltage terminal T_{C}101 of the variable current source 102. That is, the circuit including the variable capacitance diode D101 and D102 is connected in parallel with the inductor L101. The inductor L101 and the variable capacitance diode D101 and D102 form a parallel LC tank circuit.

The negative resistor 107 includes two N-channel transistors N103 and N104. The drain of the N-channel transistor N103 is connected with the output terminal Tₒᵤₜ101 of the LC circuit 106, the source is connected with the ground line GND, and the gate is connected with the output terminal Tₒᵤₜ102. The drain of the N-channel transistor N104 is connected with the output terminal Tₒᵤₜ102, the source is connected with the ground line GND, and the gate is connected with the output terminal Tₒᵤₜ101.

The conventional LC-VCO 101 described above operates as follows. In the LC-VCO 101, a low-level signal is always applied as a bias voltage to the bias terminal T_{B}101 of the variable current source 102 such that the P-channel transistor P101 is always in an on-state.

When a high-level signal is applied as a control voltage to the control voltage terminal T_{C}101, the P-channel transistor P102 turns off. In this state, the source of the N-channel transistor N101 is connected to the power supply line VCC only through the P-channel transistor P101. This causes the gate voltage of the N-channel transistor N101 to become higher than the ground voltage. As a result, the N-channel transistor N101 turns on, and a current flows through a path including the power supply line VCC, the P-channel transistor P101, the node 111, the N-channel transistor N101, and the ground line GND.

Because the gate of the N-channel transistor N101 and the gate of the N-channel transistor N102 are at the same voltage, the N-channel transistor N102 also turns on when the N-channel transistor N101 turns on. Thus, the node 112 is connected to the ground line GND via the N-channel transistor N102.

As a result, a low-level voltage is applied to both the gate of the P-channel transistor P103 and the gate of the P-channel transistor P104, and thus the P-channel transistors P103 and P104 both turn on. Thus, the node 113 of the negative resistor 105 is connected to the power supply line VCC via the P-channel transistor P104.

As a result, the LC circuit 106 is electrically excited, and the LC circuit 106 starts to oscillate. Thus, complementary AC signals with a frequency equal to the resonant frequency of the LC circuit 106 are output from the output terminals Tₒᵤₜ101 and Tₒᵤₜ102.

However, the oscillation cannot be maintained only by the LC circuit 106, because a loss of current due to parasitic resistance causes the oscillation to cease sooner or later. To maintain the oscillation, a current is supplied to the LC circuit 106 by the negative resistors 105 and 107. More specifically, when the voltage of the output terminal Tₒᵤₜ101 becomes low and the voltage of the output terminal Tₒᵤₜ102 becomes high, the P-channel transistor P105 turns off and the N-channel transistor N103 turns on. As a result, the ground voltage is applied to the output terminal Tₒᵤₜ101. Furthermore, in this state, the P-channel transistor P106 turns on and the N-channel transistor N104 turns off, and thus the power supply voltage is applied to the output terminal Tₒᵤₜ102. On the other hand, when the voltage of the output terminal Tₒᵤₜ101 becomes high and the voltage of the output terminal Tₒᵤₜ102 becomes low, the power supply voltage is applied to the output terminal Tₒᵤₜ101 and the ground voltage is applied to the output terminal Tₒᵤₜ102. As a result, the oscillation is maintained without having attenuation, and the oscillation signal is continually output from the output terminals Tₒᵤₜ101 and Tₒᵤₜ102.

In the present state, because the high-level control voltage is applied to the cathodes of the variable capacitance diodes D1 and D2 via the control voltage terminal T_{C}101 and the node 114, the capacitance of each of the variable capacitance diodes D1 and D2 decreases, and thus the oscillation frequency f increases in accordance with equation (1).

If the control voltage is lowered from the present value, the voltage applied to the cathodes of the variable capacitance diodes D1 and D2 becomes lower, and thus the capacitance of each of the variable capacitance diodes D1 and D2 increases. As a result, the oscillation frequency f decreases according to equation (1). This results in an increase in required current, in accordance with equations (1) and (2). The increase in the current supplied to the LC circuit 106 is achieved by the following operation.

The reduction in the control voltage causes the gate voltage of the P-channel transistor P102 of the variable current source 102 to go gown, and thus a current starts to flow through the P-channel transistor P102. This results in an increase in gate voltage of the N-channel transistors N101 and N102, which results in an increase in current flowing through the N-channel transistors N101 and N102. As a result, the gate voltages of the P-channel transistors P103 and P104 drop down, and thus currents flowing through the P-channel transistors P103 and P104 increase. As a result, the voltage of the node 113 goes up, and the current supplied to the LC circuit 106 increases.

In the conventional LC-VCO 101, as described above, the control voltage applied to the cathodes of the variable capacitance diodes D1 and D2 in the LC circuit 106 is also applied to the gate of the P-channel transistor P102 of the variable current source 102, thereby making it possible to change the current supplied to the LC circuit 106 depending on the oscillation frequency.

However, the conventional technique described above has following problems. FIG. 2 is a graph illustrating a C-V curve, that is, the capacitance of the variable capacitance diode as a function of the control voltage, wherein the horizontal axis represents the control voltage and the vertical axis represents the capacitance of the variable capacitance diode. In the conventional LC-VCO 101 shown in FIG. 1, the capacitance of the variable capacitance diode is varied while controlling the supplied current. However, in the variable capacitance diode used as the variable capacitor, as shown in FIG. 2, the C-V curve changes sharply in a particular voltage range 120 in which the capacitance is very sensitive to a change in control voltage. If the capacitance and the current are both varied in this voltage range 120, the operation of the LC-VCO 101 becomes unstable, and the instability results in an increase in phase noise. Furthermore, in the LC-VCO 101, because a change in control voltage results in a change in current, a fluctuation in control voltage results in a fluctuation in current and thus results in a fluctuation in oscillation frequency, which results in an increase in phase noise.

### SUMMARY OF THE INVENTION

It is an object of the present invention to provide a high-stability voltage-controlled oscillator that is low in phase noise.

A voltage-controlled oscillator according to the present invention comprises a resonator including first and second output terminals, for generating complementary oscillating AC signals output from the first and second output terminals, respectively, an amplification unit for maintaining upper peak levels of waveforms of the signals output from the first and second output terminals at a first electric potential and maintaining lower peak levels of the waveforms at a second electric potential lower than the first electric potential, and a power supply circuit for applying at least one of the first electric potential and the second electric potential to the amplification unit, wherein the capacitance of the resonator is capable of being varied continuously and also stepwisely, and wherein when the capacitance of the resonator is varied stepwisely, at least one of the first electric potential and the second electric potential is varied stepwisely such that the difference between the first electric potential and the second electric potential increases with increasing capacitance of the resonator.

In this voltage-controlled oscillator according to the present invention, when the capacitance of the resonator is changed continuously, the difference between the first electric potential and the second electric potential is not changed, and thus instability of operation does not occur. However, when the capacitance of the resonator is changed stepwisely, the potential difference is changed stepwisely so as to adjust the current supplied to the resonator. This makes it possible to reduce phase noise while maintaining stability of operation. Furthermore, in the voltage-controlled oscillator according to the present invention, it is possible to change the capacitance of the resonator continuously and it is also possible to change the capacitance of the resonator stepwisely, thereby making it possible to change the oscillation frequency over a wide range while maintaining the low tuning sensitivity of the oscillation frequency. To change the oscillation frequency over the wide range, it is necessary to change the current supplied to the resonator over a wide range. In the present invention, this is achieved by switching the electric potential stepwisely thereby making a great change in current. This prevents phase noise from increasing.

Preferably, the resonator includes an inductor connected between the first and second output terminals, a variable capacitance element connected in parallel with the inductor, one or more capacitor pairs, one electrode of each of capacitors of each capacitor pair being connected with the first or second output terminal, and one or more first switches to which one or more control signals are applied, each first switch serving to switch the connection of a corresponding capacitor pair in accordance with a control signal applied thereto between a state in which a third electric potential is applied to the other electrode of each of capacitors of the capacitor pair and a state in which the other electrode of each of capacitors of the capacitor pair is in a floating state. And the power supply circuit includes one or more second switches and a current mirror circuit. The one or more second switches are connected in parallel with each other, one terminal of each of the second switches being applied with a fourth electric potential. The second switches are controlled in accordance with the one or more control signals applied thereto such that the second switches connect the one terminal of the second switches to the other terminal thereof when the third electric potential is applied to the other electrode of each capacitor of the capacitor pair by the first switches. The current mirror circuit is disposed between a first node and a second node or between a third node and a fourth node, the first node being applied with a fifth electric potential higher than the first electric potential, the second node is located in the amplification unit and is applied with the first electric potential, the third node is applied with a sixth electric potential lower than the second electric potential, the fourth node is located in the amplification unit and is applied with the second electric potential, the current mirror circuit is connected with the other electrode of each second switch, and the current mirror circuit serves to pass, between the first node and the second node, a current proportional to the total current flowing through the one or more second switches thereby applying the first electric potential to the amplification unit or to pass, between the third node and the fourth node, a current proportional to the total current flowing through the one or more second switches thereby applying the second electric potential to the amplification unit.

In this configuration, the connection of each capacitor pair is switched by a corresponding first switch in accordance with the control signal applied to the corresponding first switch between the state in which the third electric potential is applied to the capacitor pair and the state in which the capacitor pair is floated, thereby switching the capacitance of the resonator stepwisely and thus switching the oscillation frequency stepwisely. At the same time, the second switches are opened or closed by the respective same control signals as those applied to the corresponding first switches such that the total current flowing through the second switches is changed stepwisely so that a current proportional to the total current flowing through the second switches is passed through the current mirror circuit thereby changing the first or second electric potential stepwisely.

The first and second switches may be N-channel transistors. In this case, when a high-level voltage is applied as a control signal to one of the first switches and the corresponding one of the second switches, the one of the first switches causes the third electric potential to be applied to the other electrode of each capacitor of a corresponding capacitor pair, and the one of the second switches turns on such that one electrode thereof is connected with the other electrode thereof, while when a low-level voltage is applied as a control signal to one of the first switches and the corresponding one of the second switches, the one of the first switches causes the other electrode of each capacitor of a corresponding capacitor pair to be brought into a floating state, and the one of the second switches turns off such that one electrode thereof and the other electrode thereof are isolated from each other. Alternatively, the first and second switches may be N-channel transistors. In this case, when a low-level voltage is applied as a control signal to one of the first switches and the corresponding one of the second switches, the one of the first switches causes the third electric potential to be applied to the other electrode of each capacitor of a corresponding capacitor pair, and the one of the second switches turns on such that one electrode thereof is connected with the other electrode thereof, while when a high-level voltage is applied as a control signal to one of the first switches and the corresponding one of the second switches, the one of the first switches causes the third electric potential to be applied to the other electrode of each capacitor of a corresponding capacitor pair, and the one of the second switches turns on such that one electrode thereof is connected with the other electrode thereof.

### BRIEF DESCRIPTION OF THE DRAWINGS

FIG. 1 is a circuit diagram illustrating an equivalent circuit of a conventional LC-VCO;

FIG. 2 is a graph showing the dependence of the capacitance of a variable capacitance diode on a control voltage, wherein the horizontal axis represents the control voltage and the vertical axis represents the capacitance of the variable capacitance diode; and

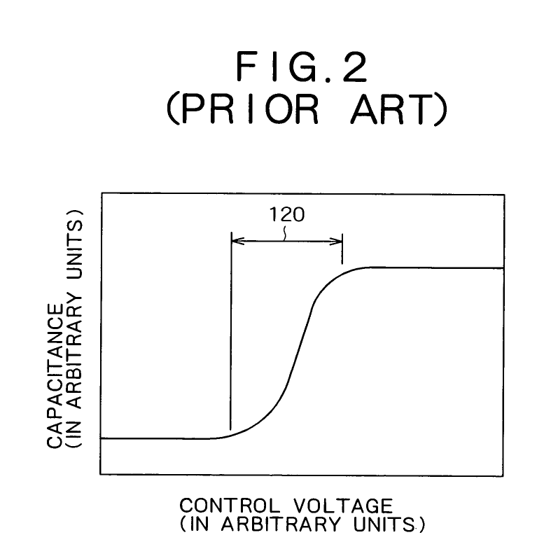

FIG. 3 is a circuit diagram illustrating an equivalent circuit of a voltage-controlled oscillator according to an embodiment of the present invention.

### DETAILED DESCRIPTION OF THE PREFERRED EMBODIMENTS

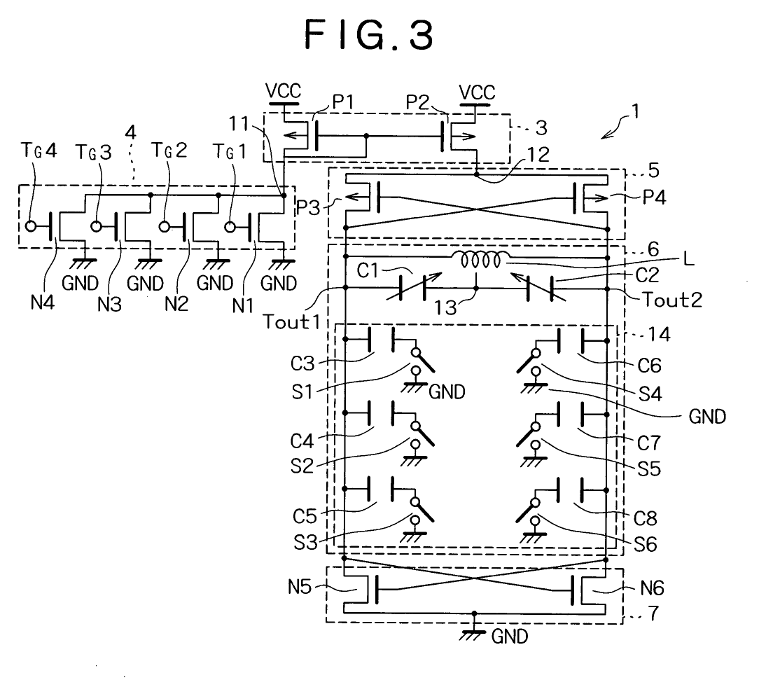

The present invention is described in further detail below with reference to embodiments in conjunction with the accompanying drawings. FIG. 3 is a circuit diagram illustrating an equivalent circuit of a voltage-controlled oscillator according to an embodiment of the present invention. As shown in FIG. 3, the voltage-controlled oscillator (LC-VCO) 1 according to the present embodiment is connected with a power supply line VCC and a ground line GND. The LC-VCO 1 is constructed in the form of, for example, an integrated circuit on a semiconductor substrate (not shown). For example, the LC-VCO 1 is used as a local oscillator (LO) in a phase locked loop (PLL) circuit used for frequency multiplication or phase synchronization.

The LC-VCO 1 according to the present embodiment includes a current mirror circuit 3 connected with the power supply line VCC. Between the current mirror circuit 3 and the ground line GND, there is provided a current controller 4 for controlling the magnitude of the current passed through the current mirror circuit 3. The current mirror circuit 3 and the current controller 4 form a power supply circuit. Between the current mirror circuit 3 and the ground line GND, a negative resistor 5, an LC circuit 6 serving as a resonator, and a negative resistor 7 are disposed in parallel with the current controller 4 in the order described above from the current mirror circuit 3 to the ground line GND. The negative resistors 5 and 7 form an amplification unit.

The current mirror circuit 3 includes two P-channel transistors P1 and P2. The drains of the P-channel transistors P1 and P2 are connected with the power supply line VCC, and the gates thereof are both connected with a node 11. The source of the P-channel transistor P1 is connected with the node 11, and the source of the P-channel transistor P1 is connected with the node 12.

The current controller 4 includes four N-channel transistors N1 to N4 serving as switches that are connected in parallel with each other and that are disposed between the node 11 of the current mirror circuit 3 and the ground line GND. The drains of the N-channel transistors N1 to N4 are connected in common with the node 11, and the sources of the N-channel transistors N1 to N4 are connected with the ground line GND. A bias voltage is applied to the gate terminal T_{G}1 of the N-channel transistor N1, and control voltages V₂, V₃, and V₄ are respectively applied to the gate terminals T_{G}2, T_{G}3, and T_{G}4 of the N-channel transistors N2, N3, and N4. The bias signal is given in the form of an analog signal that can take an arbitrary voltage in a predetermined range. The control voltages V₂, V₃, and V₄ are given in the form of a digital signal that can take either one of two levels, that is, high and low levels. The N-channel transistors N1 to N3 function as second switches.

The negative resistor 5 includes two P-channel transistors P3 and P4, the drains of which are connected with the power supply line VCC.

The LC circuit 6 has output terminals Tₒᵤₜ1 and Tₒᵤₜ2 via which complementary signals from the LC circuit 6 are output. The output terminal Tₒᵤₜ1 is connected with the source of the P-channel transistor P3 and also with the gate of the P-channel transistor P4. The output terminal Tₒᵤₜ2 is connected with the source of the P-channel transistor P4 and also with the gate of the P-channel transistor P3.

An inductor L is connected between the output terminals Tₒᵤₜ1 and Tₒᵤₜ2. The inductor L is, for example, a spiral inductor formed in a top layer of a plurality of interconnection layers formed on a semiconductor substrate. Furthermore, variable capacitance elements C1 and C2 are connected in series between the output terminals Tₒᵤₜ1 and Tₒᵤₜ2. That is, the series connection of variable capacitance elements C1 and C2 is connected in parallel with the inductor L. The variable capacitance elements C1 and C2 are capacitors whose capacitance varies depending on an applied control voltage. For example, varactors or variable capacitance diodes may be employed as the variable capacitance elements C1 and C2. A control voltage V₁ is applied to a node 13 between the variable capacitance elements C1 and C2, wherein the control voltage V₁ is given as an analog signal that can continuously vary within a predetermined range.

The LC circuit 6 includes a capacitor-and-switch unit 14 connected with the output terminal Tₒᵤₜ1 or the output terminal Tₒᵤₜ2. The capacitor-and-switch unit 14 includes switched-capacitors C3 to C8 and switches S1 to S6. One electrode of each of capacitors C3 to C5 is connected with the output terminal Tₒᵤₜ1, and second electrodes of the capacitors C3 to C5 are respectively connected with switches S1 to S3. One electrode of each of capacitors C6 to C8 is connected with the output terminal Tₒᵤₜ2, and second electrodes of the capacitors C6 to C8 are respectively connected with switches S4 to S6. The switches S1 to S6 are used to switch the connection between a state in which the second electrode of each of capacitors C3 to C8 is grounded and a state in which the second electrode is floating.

The operations of the switches S1 and S4 are controlled by the control voltage V₂. For example, N-channel transistors are used as the switches S1 and S4. For example, an N-channel transistor serving as the switch S1 is connected such that the control voltage V₂ is applied to its gate, the drain thereof is connected with the electrode, other than the electrode connected with the output terminal Tₒᵤₜ1, of the capacitor C3, and the source is connected with the ground line GND. This N-channel transistor serving as the switch S1 turns on when the control voltage V₂ is high thereby connecting the electrode of the capacitor C3 to the ground line GND. On the other hand, when the control voltage V₂ is low, this N-channel transistor turns off thereby bringing the electrode of the capacitor C3 into a floating state. An N-channel transistor serving as the switch S4 is connected in a similar manner and operates in a similar manner to the N-channel transistor serving as the switch S1. The switches S1 and S4 form a first switch pair. Similarly, switches S2 and S5 are realized by N-channel transistors, and the operations of the switches S2 and S5 are controlled by the control voltage V₃. More specifically, when the control voltage V₃ is high, the switches S2 and S5 turn on thereby connecting one electrode of each of the capacitors C4 and C7 to the ground line GND. On the other hand, when the control voltage V₃ is low, the switches S2 and S5 turn off thereby bringing the electrode of each of the capacitors C4 and C7 into a floating state. The switches S2 and S5 form another first switch pair. Switches S3 and S6 are realized by N-channel transistors the operations of which are controlled by the control voltage V₄ such that when the control voltage V₄ is high, the switches S3 and S6 turn on thereby connecting one electrode of each of each of the capacitors C5 and C8 to the ground line GND, while when the control voltage V₄ is low, the switches S3 and 6 turn off thereby bringing the electrode of each of the capacitors C5 and C8 into a floating state. The switches S3 and S6 form still another first switch pair.

The negative resistor 7 includes two N-channel transistors N5 and N6, wherein the N-channel transistor N5 is connected such that its drain is connected with the output terminal Tₒᵤₜ1 of the LC circuit 6, the source is connected with the ground line GND, and the gate is connected with the output terminal Tₒᵤₜ2, and the N-channel transistor is connected such that its drain is connected with the output terminal Tₒᵤₜ2, the source is connected with the ground line GND, and the gate is connected with the output terminal Tₒᵤₜ1.

In the present embodiment, the P-channel transistors and the N-channel transistor may be, for example, PMOSFETs (P-type Metal Oxide Semiconductor Field Effect Transistors) and NMOSFETs, respectively.

The LC-VCO 1 operates as follows. First, the operation is described for a case in which the control voltages V₂, V₃, and V₄ are low. If a proper bias voltage is applied to the gate terminal T_{G}1 of the N-channel transistor N1 of the current controller 4, the N-channel transistor N1 turns on and a current flows through the N-channel transistor N1. However, the N-channel transistors N2 to N4 are maintained in off-states because the control voltages V₂, V₃, and V₄ are low. As a result, the node 11 is connected with the ground line GND only through the N-channel transistor N1.

This causes the node 11 to be at a particular voltage lower than the power supply voltage. As a result, the P-channel transistor P1 turns on and a current flows through the P-channel transistor P1, and the P-channel transistor P2 also turns on and a current proportional to the current flowing through the P-channel transistor P1 flows through the P-channel transistor P2. As a result, the node 12 goes to a particular voltage higher than the ground voltage.

As a result, the LC circuit 6 is electrically excited, and the LC circuit 6 starts to oscillate. Thus, complementary AC signals with a frequency equal to the resonant frequency of the LC circuit 6 are output from the output terminals Tₒᵤₜ1 and Tₒᵤₜ2.

The negative resistors 5 and 7 supply currents to the LC circuit 6 so that the resonant oscillation is maintained. For example, when the output terminal Tₒᵤₜ1 becomes low and the output terminal Tₒᵤₜ2 becomes high during the oscillation, the P-channel transistor P3 turns off and the N-channel transistor N5 turns on. As a result, the ground voltage is applied to the output terminal Tₒᵤₜ1. On the other hand, the P-channel transistor P4 turns on and the N-channel transistor N6 turns off, and thus a voltage higher than the ground voltage is supplied to the output terminal Tₒᵤₜ2 from the node 12. On the other hand, when the output terminal Tₒᵤₜ1 becomes high and the output terminal Tₒᵤₜ2 becomes low, the voltage of the node 12 is applied to the output terminal Tₒᵤₜ1, and the ground voltage is applied to the output terminal Tₒᵤₜ2. As described above, the negative resistors 5 and 7 allow that the high level in the complementary oscillation signals output from the output terminals Tₒᵤₜ1 and Tₒᵤₜ2 is maintained at the voltage of the node 12, and the low level is maintained at the ground voltage, thereby maintaining the oscillation without encountering attenuation.

In the state described above, the control voltages V₂, V₃, and V₄ are all low, and thus the switches S1 to S6 are all opened. That is, the electrode, opposite to the electrode connected with the output terminal Tₒᵤₜ1 or Tₒᵤₜ2, of each of the capacitors C3 to C8 is in a floating state. Therefore, the capacitors C3 to C8 do not function as capacitors, and the total capacitance of the capacitor-and-switch unit 14 includes only parasitic capacitance. That is, the capacitance of the LC circuit 6 is given substantially only by the variable capacitance elements C1 and C2, and thus the LC circuit 6 has low capacitance. As a result, the oscillation occurs at a high frequency according to equation (1).

In this state, if the capacitance of the variable capacitance elements C1 and C2 are varied by controlling the control voltage V₁ applied to the node 13, the oscillation frequency is varied continuously. Furthermore, the voltage of the node 12 can be controlled by controlling the bias voltage applied to the gate terminal T_{G}1 thereby controlling the current flowing through the N-channel transistor N1 of the current controller 4 and thus supplying an optimum current to the LC circuit 6.

When a high-level voltage is applied as one or more of the control voltages V₂, V₃, and V₄, the LC-VCO 1 operates as follows. By way of example, let us assume that a high-level voltage is applied as the control voltage V₂ while maintaining the control voltages V₃ and V₄ at the low level. The high-level voltage applied as the control voltage V₂ causes the switches S1 and S4 of the LC circuit 6 to be closed, and thus the electrode, opposite to the electrode connected with either the output terminal Tₒᵤₜ1 or Tₒᵤₜ2, of each of the capacitors C3 and C6 is connected to the ground line GND. This causes the capacitors C3 and C6 to function as capacitors, and thus the total capacitance of the LC circuit 6 increases. As a result, the oscillation occurs at a lower frequency according to equation (1). That is, if an increase in the capacitance of the capacitor-and-switch unit 14 caused by the capacitors C3 and C6 is expressed by C1, then the oscillation frequency f₁ is given by equation (4) described below, for the control voltage V₂ at the high level.

$${f}_{1} = \frac{1}{2 π \sqrt{L \times ( C + {C}_{1} )}} \qquad ( 4 )$$

The increase in capacitor of the LC circuit 6 results in an increase in current needed by the LC circuit 6 according to equation (2). This necessary increase in current can be achieved as follows. That is, the transition of the control voltage V₂ to the high level causes the N-channel transistor N2 of the current controller 4 to turn on, and thus a current starts to flow through each of the two N-channel transistors N1 and N2. In this state, compared with the state in which the N-channel transistors N2 to N4 are all in the off-state, the voltage of the node 11 becomes lower, and the current flowing through the P-channel transistor P1 and the current flowing through the P-channel transistor P2 increase. As a result, the voltage of the node 12 becomes higher, and the current supplied to the LC circuit 6 increases. This prevents the LC circuit 6 from encountering insufficiency of current.

When the control voltage V₂ is at the high level, if the control voltage V₃ and/or the control voltage V₄ is also raised up to a high level, the oscillation frequency is reduced to a further lower value, and the current supplied to the LC circuit 6 is further increased.

In the LC-VCO 1 according to the present embodiment, as described above, the oscillation frequency can be switched stepwisely by switching the levels of the control voltages V₂, V₃, and/or V₄. In response to the switching of the oscillation frequency, the current supplied to the LC circuit 6 is also switched stepwisely to an adequate value so that the oscillation is maintained without ceasing due to insufficiency of the supplied current and without encountering an increase in phase noise due to an excessive supply of current. Note that instability does not occur in the operation of the LC-VCO 1 when the oscillation frequency is changed continuously by changing the control voltage V₁, because the current supplied to the LC circuit 6 is not changed in this case.

In the present embodiment, the capacitance of the LC circuit 6 can be changed continuously by changing the capacitance of the variable capacitance elements C1 and C2 and can be changed stepwisely by turning on or off the switches S1 to S6. This makes it possible to control the oscillation frequency over a wide range while maintaining the low tuning sensitivity of the oscillation frequency. To change the oscillation frequency over the wide range, it is necessary to change the current supplied to the resonator over a wide range. In the LC-VCO 1 according to the present invention, the above requirement is met, because it is possible to change the current supplied to the LC circuit 6 over the wide range as described above, and thus no increase in phase noise occurs.

Although in the embodiment described above, three control voltages are applied to three respective N-channel transistors N2 to N4 disposed in the current controller 4, and the same three control voltages are applied to three respective switch sets S1 to S6 and the switched-capacitors C3 to C8 disposed in the LC circuit 6, the configuration of the control voltages and associated parts is not limited to that employed in the embodiment described above. For example, two or less control voltages or four or more control voltage may be used, and a corresponding number of N-channel transistors and a corresponding number of switches and switched-capacitors may be provided.

Instead of the N-channel transistors N1 to N4, P-channel transistors or CMOS transistors may be used. Instead of using N-channel transistors to realize the switches S1 to S6, another type of device may be used. In a case in which P-channel transistors are used instead of the N-channel transistors N1 to N4, and the switches S1 to S6 are realized using P-channel transistors, those P-channel transistors are controlled such that they turn on when a low-level voltage is applied thereto as a control voltage.

The current mirror circuit 3 may be disposed between the negative resistor 7 and the ground line GND. In the current mirror circuit 3, N-channel transistors may be used instead of the P-channel transistors P1 and P2. In this case, the current controller 4 may be disposed between the current mirror circuit 3 and the power supply line VCC.

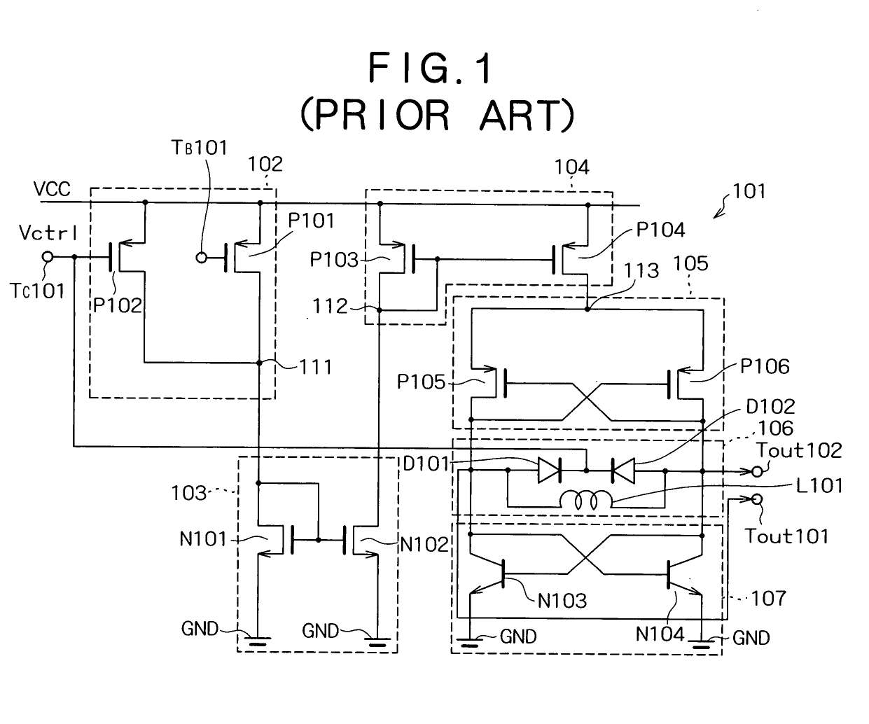

Each part in the equivalent circuit shown in FIG. 1 does not necessarily need to be formed of a single element, but each part may be formed of a plurality of elements, as long as the function of each part is achieved. For example, the switch S1 does not necessarily need to be formed of one N-channel transistor, but the switch S1 may be realized by another switching element or by a circuit including a plurality of elements.

The channel width may be different among the N-channel transistors N2 to N4, and the capacitance may be different among the capacitors C3 to C8. By employing a proper combination of capacitors, it is possible to switch the capacitance of the capacitor-and-switch unit 14 among a greater number of values, that is, it is possible to control the oscillation frequency more precisely.

The electrodes, opposite to the electrodes connected with either one of output terminals, of respective capacitors C3 and C6 may be connected with each other. In this case, a single switch may be used to switch the connection between a floating state and a state in which the electrodes of the capacitors C3 and C6 are connected with the ground line GND. Electrodes of the capacitors C4 and C7 may be connected with each other in a similar manner, and/or electrodes of the capacitors C5 and C8 may be connected with each other.

In the present invention, as described above, when the capacitance of the resonator is changed stepwisely, the potential difference between the first electric potential and the second electric potential is changed stepwisely by the power supply circuit thereby adjusting the current supplied to the resonator, and thus achieving high stability in operation and low phase noise.

What is claimed is:

1. A voltage-controlled oscillator comprising:
a resonator including first and second output terminals, for generating complementary oscillating AC signals output from the first and second output terminals, respectively;
an amplification unit for maintaining upper peak levels of waveforms of the signals output from the first and second output terminals at a first electric potential and maintaining lower peak levels of the waveforms at a second electric potential lower than the first electric potential; and
a power supply circuit for applying at least one of the first electric potential and the second electric potential to the amplification unit,
wherein the capacitance of the resonator is capable of being varied continuously and also stepwisely, and wherein when the capacitance of the resonator is varied stepwisely, at least one of the first electric potential and the second electric potential is varied stepwisely such that the difference between the first electric potential and the second electric potential increases with increasing capacitance of the resonator.

2. A voltage-controlled oscillator according to claim 1, wherein
the resonator includes
an inductor connected between the first and second output terminals;
a variable capacitance element connected in parallel with the inductor;
one or more capacitor pairs, one electrode of each of capacitors of each capacitor pair being connected with the first or second output terminal; and
one or more first switches to which one ore more control signals are applied, each first switch serving to switch the connection of a corresponding capacitor pair in accordance with a control signal applied thereto between a state in which a third electric potential is applied to the other electrode of each of capacitors of the capacitor pair and a state in which the other electrode of each of capacitors of the capacitor pair is in a floating state; and
the power supply circuit includes
one or more second switches; and
a current mirror circuit,
the one or more second switches being connected in parallel with each other, one terminal of each of the second switches being applied with a fourth electric potential, the second switches being controlled in accordance with said one or more control signals applied thereto such that the second switches connect the one terminal of the second switches to the other terminal thereof when the third electric potential is applied to the other electrode of each capacitor of the capacitor pair by said first switches,
the current mirror circuit being disposed between a first node and a second node or between a third node and a fourth node, the first node being applied with a fifth electric potential higher than the first electric potential, the second node is located in the amplification unit and is applied with the first electric potential, the third node is applied with a sixth electric potential lower than the second electric potential, the fourth node is located in the amplification unit and is applied with the second electric potential, the current mirror circuit is connected with the other electrode of each second switch, and the current mirror circuit serves to pass, between the first node and the second node, a current proportional to the total current flowing through the one or more second switches thereby applying the first electric potential to the amplification unit or to pass, between the third node and the fourth node, a current proportional to the total current flowing through the one or more second switches thereby applying the second electric potential to the amplification unit.

3. A voltage-controlled oscillator according to claim 2, wherein
the first and second switches are N-channel transistors; and
when a high-level voltage is applied as a control signal to one of the first switches and the corresponding one of the second switches, the one of the first switches causes the third electric potential to be applied to the other electrode of each capacitor of a corresponding capacitor pair, and the one of the second switches turns on such that one electrode thereof is connected with the other electrode thereof, while when a low-level voltage is applied as a control signal to one of the first switches and the corresponding one of the second switches, the one of the first switches causes the other electrode of each capacitor of a corresponding capacitor pair to be brought into a floating state, and the one of the second switches turns off such that one electrode thereof and the other electrode thereof are isolated from each other.

4. A voltage-controlled oscillator according to claim 2, wherein
the one or more second switches being connected in parallel with each other, one terminal of each of the second switches being applied with a fourth electric potential, the second switches being controlled in accordance with the one or more control signals applied thereto such that when, in accordance with a control signal, the first switch switches the connection of the capacitor pair corresponding to the first switch into the state in which the third electric potential is applied to the other electrode of each capacitor of the capacitor pair, a corresponding second switch to which the same control signal is applied turns on such that one terminal of the second switch is connected with the other terminal thereof, the current mirror circuit being disposed between a first node and a second node or between a third node and a fourth node, the first node being applied with a fifth electric potential higher than the first electric potential, the second node being located in the amplification unit and being applied with the first electric potential, the third node being applied with a sixth electric potential lower than the second electric potential, the fourth node being located in the amplification unit and being applied with the second electric potential, the current mirror circuit being connected with the other electrode of each second switch, the current mirror circuit serving to pass, between first node and the second node, a current proportional to the total current flowing through the one or more second switches thereby applying the first electric potential to the amplification unit or to pass, between the third node and the fourth node, a current proportional to the total current flowing through the one or more second switches thereby applying the second electric potential to the amplification unit.
the first and second switches are P-channel transistors; and
when a low-level voltage is applied as a control signal to one of the first switches and the corresponding one of the second switches, the one of the first switches causes the third electric potential to be applied to the other electrode of each capacitor of a corresponding capacitor pair, and the one of the second switches turns on such that one electrode thereof is connected with the other electrode thereof, while when a high-level voltage is applied as a control signal to one of the first switches and the corresponding one of the second switches, the one of the first switches causes the third electric potential to be applied to the other electrode of each capacitor of a corresponding capacitor pair, and the one of the second switches turns on such that one electrode thereof is connected with the other electrode thereof.

5. A voltage-controlled oscillator according to claim 2, wherein the current mirror circuit includes a first P-channel transistor the drain and the source of which are connected with the first node and the second node, respectively, or with the fourth node and the third node, respectively; and a second P-channel transistor the drain of which is applied with a seventh electric potential higher than the fourth electric potential, the source of which is connected with the other electrode of each second switch, and the gate of which is connected with the gate of the first P-channel transistor and also with the other electrode of each second switch.

6. A voltage-controlled oscillator according to claim 2, wherein the current mirror circuit includes a first N-channel transistor the drain and the source of which are connected with the first node and the second node, respectively, or with the fourth node and the third node, respectively; and a second N-channel transistor the source of which is applied with an eighth electric potential lower than the fourth electric potential, the drain of which is connected with the other terminal of each second switch, and gate of which is connected with the gate of the first N-channel transistor and also with the other electrode of each second switch.

7. A voltage-controlled oscillator according to claim 2, wherein the variable capacitance element is a varactor to which another control voltage is applied and whose capacitance varies depending on the applied control voltage.

8. A voltage-controlled oscillator according to of claim 2, wherein the inductor is a spiral inductor formed on a substrate.

9. A voltage-controlled oscillator according to claim 2, wherein the fifth voltage is a power supply voltage, and the sixth voltage is a ground voltage.

10. A voltage-controlled oscillator according to claim 1, wherein the amplification unit includes a third P-channel transistor, a fourth P-channel transistor, a third N-channel transistor, and a fourth N-channel transistor, the drain of the third P-channel transistor being applied with the first electric potential, the source of the third P-channel transistor being connected with the first output terminal, the gate of the third P-channel transistor being connected with the second output terminal, the drain of the fourth P-channel transistor being applied with the first electric potential, the source of the fourth P-channel transistor being connected with the second output terminal, the gate of the fourth P-channel transistor being connected with the first output terminal, the source of the third N-channel transistor being applied with the second electric potential, the drain of the third N-channel transistor being connected with the first output terminal, the gate of the third N-channel transistor being connected with the second output terminal, the source of the fourth N-channel transistor being applied with the second electric potential, the drain of the fourth N-channel transistor being connected with the second output terminal, the gate of the fourth N-channel transistor being connected with the first output terminal.

11. A voltage-controlled oscillator according to claim 1, wherein the voltage-controlled oscillator is a local oscillator in a phase locked loop.
